(19) United States
(12) Patent Application Publication
(10) Pub. No.: US 2026/0085443 A1
(43) Pub. Date: Mar. 26, 2026

(54) PVT METHOD AND APPARATUS FOR PRODUCING SINGLE CRYSTALS IN A SAFE PROCESS

(71) Applicant: PVA TEPLA AG, Wettenberg (DE)

(72) Inventors: Tomas BAUMECKER, Grünberg (DE); Karsten VIEHMANN, Hüttenberg (DE); Lorenz VOGEL, Staufenberg (DE); Michael SCHÖLER, Insingen (DE); Lukas EWERT, Giessen (DE); Tobias ECKER, Hüttenberg (DE)

(21) Appl. No.: 19/108,097

(22) PCT Filed: Sep. 15, 2023
(86) PCT No.: PCT/DE2023/100696

§ 371 Date: Feb. 28, 2025

(30) Foreign Application Priority Data
Sep. 16, 2022 (DE) 10 2022 123 747.8
Sep. 16, 2022 (DE) 10 2022 123 757.5

(51) Int. Cl. C30B 23/06; C30B 23/00; C30B 27/00

(52) U.S. Cl. CPC C30B 23/06; C30B 23/005; C30B 27/00

(57) ABSTRACT

An apparatus for process-safe production of single crystals includes a process chamber that is fillable with a process gas and that receives a heatable growth cell, a heating device for heating the growth cell, which is adapted to receive a source material and a seed, and a vessel at least radially enclosing the process chamber and comprising at least first and second segments. A related method is also disclosed.

### TECHNICAL FIELD

The present disclosure relates to a PVT method for process-safe fabrication of single crystals, and an apparatus comprising a highly heatable growth cell, a process chamber in which the growth cell is located, and a heater surrounding the process chamber for heating the growth cell. A source material and a seed can be introduced into the growth cell, the process chamber can be filled with a process gas, and the growth cell can be heated so that the source material sublimates and resublimates on the seed.

### BACKGROUND AND SUMMARY OF PRESENT DISCLOSURE

In an industrial environment, the so-called Physical Vapor Transport (PVT) process is considered the standard method for the production of monocrystalline silicon carbide (SiC) crystals. The source material is usually a powder containing many different cristallites. It is also possible to use volume crystals. The High-Temperature Chemical Vapor Deposition (HT-CVD) process is known as an alternative process. In the PVT process, crystal growth typically takes place within the growth cell consisting of graphite by sublimation of a SiC source material and crystallization on a predetermined SiC seed at temperatures above 2,000° C. The driving force for crystal growth is a temperature gradient imposed on the growth cell by a heating device. Common methods for heating PVT apparatus use resistance heaters or induction heaters. In induction heating, the growth cell (hot zone) of the vacuum-tight process chamber is surrounded by a non-conductive material, typically (quartz) glass. Process gases are contained or introduced in the process chamber, which are used, among other things, to influence crystal growth. The process chamber can be single- or double-walled and air- or water-cooled. The process gases typically used are argon, helium, nitrogen, hydrogen and possibly other gases for targeted doping. The process pressure can range from vacuum conditions to atmospheric pressure. In common processes for the production of doped SiC monocrystals, no hydrogen or only small concentrations are used.

SiC single crystals are produced for a wide range of applications in semiconductor technology due to their large bandgap and high thermal conductivity. The underlying process for the production of SiC single crystals has therefore already been the subject of many descriptions. As an example, reference is made to US 2011/0300323 A1. According to this, an inert gas is used as the process gas, which is unproblematic from a safety point of view. With regard to the state of the art, reference is also made to EP 0 811 708 A2, US 2012/0086001 A1, GB 772,691, DE 60 2004 001 802 T2 and EP 3 760 765 A1.

It is an intellectual starting point and one of the tasks of the present disclosure to enable processes, inter alia, for the targeted influencing of doping incorporation or for the production of undoped SiC single crystals. With respect to this starting point, it is developed within the scope of the present disclosure to ensure a safe process, with better results than in the prior art and/or more cost-effectively than known. If necessary, this can even be carried out using a reactive gas, i.e., a combustible and/or reactive (possibly also toxic) gas, e.g. hydrogen as process gas, with concentrations of more than 5% and up to 100%.

In this process, the gas molecules of the reactive gas, such as hydrogen atoms, attach themselves to the surface of the growing single crystal, but are immediately displaced by the following sublimated components of the source material. In this case, the reactive gas molecules, such as hydrogen atoms, serve briefly as placeholders, so that a crystal lattice with few defects only, if not defect free, can develop. Reactive gas molecules can also react with other process gases, the source material, or even the hot zone material to form other gaseous species that can enter the process gas atmosphere and attach to the crystal, at least temporarily. Possible reactive gases such as silane, methane, propane, etc. provide the elements silicon and carbon, among others, which are incorporated into the crystal. Overall, the addition of reactive gases can influence the defect density (desired and/or undesired). However, the exact influence depends on a large number of parameters and their interaction. Reactive gas addition is intended to influence crystal growth.

The task of the present disclosure can thus be seen in providing an apparatus and a method with which improved or modified crystal growth is made possible.

In one aspect of the present disclosure or further development of the present disclosure, it can be considered an aspect of the task to provide a device and a method in which a reactive gas can be used to improve crystal growth.

In yet another aspect or further development of the present disclosure, the task may be to provide a device and a method by means of which improved crystals can be provided with low effort or at low(er) cost.

However, the use of a reactive gas comprising, for example, hydrogen or other reactive elements represents a potential hazard when carrying out the process. For example, a reactive gas may be flammable or ignitable and/or toxic. In the case of the example hydrogen, an oxyhydrogen reaction can occur with the oxygen in the air, which is why hydrogen is referred to as a reactive gas in the context of this description. Other examples of reactive gases currently under consideration include, in addition to hydrogen, precursors containing carbon and silicon or hydrocarbons and their derivatives (examples: silane or also methane, propane, etc.).

Furthermore, in today's equipment, the process chamber is typically formed of fused silica, which is inherently brittle and prone to breakage. However, it is particularly preferred to use quartz glass because it can withstand the high temperatures of the growth cell and because it does not shield the electromagnetic field of an induction coil or the radiant heat of a resistance heater. Similarly, a combination of induction and resistance heaters may be provided. For example, a floor or ceiling auxiliary heater can be designed as a resistance heater, while the main heater is designed as an induction heater. In principle, however, the safety requirements also apply in a similar way to other construction materials for providing the process chamber, at least in the case of quartz glass to a particular extent.

However, if the process chamber is damaged or leaks, e.g. if the quartz glass breaks, the hydrogen can mix with the oxygen in the environment and an oxyhydrogen gas is generated, which is ignited by the heating device (hot components of the hot zone, typically graphite parts inside the process chamber) and explodes. If a reactive gas is used, it is therefore not possible to carry out the process safely with the known fittings.

A reactive gas mentioned in the present description—for example hydrogen—is not to be equated with known doping gases. Known typical doping gases are not used in the concentrations desired here, and/or are neither flammable nor otherwise reactive in the sense used in this description. Doping gases are purged around the crystal, so the processes take place entirely within the process chamber. For example, in this context, the process chamber can also be purged with an inert gas such as argon to directly modify the PVT process. In general, dopant gases are intended to be incorporated into the crystal or crystal structure-from which the name “dopant gas” is derived-in order to influence physical and/or chemical properties of the crystal, such as electrical conductivity. In other words, molecules or components of a dopant gas form a later integral building material of the crystal. Such molecules or components of a dopant gas remain in the crystal and can be detected there later.

In contrast, a reactive gas such as hydrogen can influence crystal growth and dopant incorporation as a reactive component of the gas atmosphere, but is not incorporated into the crystal-like dopant gas to influence the physical and chemical properties of the crystal. Due to the hazard potential of reactive gases, such as ignition, burning off, deflagration or even poisoning potential, reactive gases have so far not been considered for use in improving crystal growth, or in any case the safety aspects of handling a reactive gas in this environment, as described above, have not been sufficiently taken into account. Furthermore, the reactive gas to be used is not a swelling material in the strict sense. In typical PVT processes, the swelling material is SiC powder. In variants of the classical PVT process such as HT-CVD, hydrogen can be used as a carrier gas, which transports the actual source material, usually gaseous C- or Si-containing precursors. The gas thus serves there as a carrier gas, i.e. as a transport medium for precursors and for dopants. Dopants can be solid, liquid or gaseous elements or compounds, typically containing nitrogen, phosphorus, aluminium, boron or vanadium.

In the context of this further development and improvement, the present description describes and defines various aspects of the containment vessel surrounding the process chamber, which was developed in-house by the applicant PVA TePla. Furthermore, the provision of a protective atmosphere, for example with inert gas, in the area between the process chamber and the vessel wall was investigated. One particular aim of the containment is to prevent or suppress an explosive gas mixture in the event of damage, for example rupture, of the process chamber.

In order to achieve process reliability, an apparatus for carrying out the process could be arranged in a vacuum cell. However, such a cell would have to be absolutely vacuum-tight and is therefore comparatively complex to manufacture, because a large number of feedthroughs are required to supply the apparatus with electricity, gas and, if necessary, cooling fluid, each of which must be prepared to be vacuum-tight. Moreover, a vacuum cell is practically impossible to maintain or repair, or it must first be opened at great expense and then closed again at great expense after the work or modification has been completed.

On the other hand, it would be advantageous to present a PVT process for the reliable production of single crystals, which can be carried out in an apparatus that can be produced with little effort and/or at low cost.

The problem is solved by the present disclosure defined in the independent claims. Dependent claims give further embodiments and preferred embodiments of the present disclosure.

For solving one, more or all of the presented aspects of the problem, a PVT method for process-safe production of single crystals in an apparatus is presented, wherein the apparatus comprises a process chamber for receiving a highly heatable growth cell and a heating means for heating the growth cell, wherein the growth cell is adapted for receiving a source material and a seed, and wherein the process chamber is fillable with a process gas and the growth cell is heatable. The apparatus comprises a containment vessel enclosing the process chamber for enclosing the process chamber preferably in a gas-tight or substantially gas-tight manner. The containment vessel thereby has a circumferential vessel wall, so that a space is created between the vessel wall of the containment vessel and the process chamber. In other words, the area extending from the inside of the vessel wall to the outside of the process chamber may be referred to as the intermediate space. For example, if the process chamber is round and the containment vessel is also round, then the interstitial space defines an annular segment (considered as a plane) or hollow cylinder of wall thickness b with inner radius r (corresponding, for example, to the wall of the process chamber), outer radius R (corresponding, for example, to the wall of the containment vessel), and height h (measured, for example, from the bottom to the lid).

The method presented herein comprises the steps of providing a protective atmosphere in the interstitial space and flooding the interstitial space with the protective atmosphere therefor, and providing the process gas in the process chamber. The process gas may comprise or consist of, for example, a reactive gas. In other words, the process defines that first the intermediate space is filled with the protective atmosphere, for example in such a way that any air that may have been present there previously has been replaced as completely as possible, and only when the containment vessel is ready for use through filling with protective atmosphere (and outputs this, for example, as a signal) is the further process sequence initiated.

In principle, process gas could be introduced into the process chamber before the containment vessel is ready for use, if the chamber is not yet so hot that ignition of the process gas is likely in the event of a leak in the process chamber. Likewise, the process chamber could be heated before the containment vessel is ready for use, for example to operating temperature, if no process gas or at least no reactive gas has been introduced there yet. The transition between the provision of the containment vessel and the start of operation of the process chamber can be smooth. However, it is overall preferred if the provision of the containment atmosphere in the interstitial space is completed before the process gas is introduced into the process chamber and/or the growth cell is heated to deployment temperature. In other words, it is preferred if the provision of the process gas in the process chamber is completed after the interstitial space is flooded with protective gas. It may therefore also be preferred that the flooding of the interstitial space with the protective atmosphere-in particular, the initial flooding of the interstitial space or the flooding of the interstitial space with a first protective atmosphere-further also comprises the replacement of air present in the interstitial space, namely before the sublimation of the source material is initiated.

It is therefore particularly advantageous if flooding of the containment vessel takes place or is completed at the latest when sublimation of the source material takes place, because high temperatures are then present which are capable of igniting the reactive gas. For safety reasons, it is advantageous if flooding of the containment vessel takes place before the reactive gas is introduced into the process chamber.

Should damage—such as rupture—occur to the process chamber in this arrangement, the reactive gas of the process chamber mixes in the protective atmosphere in the containment vessel, for example with the inert gas, to form a non-explosive gas mixture, so that an explosion cannot occur even in a hot environment. This safety measure may be particularly important if the reactive gas is flammable or tends to deflagrate, such as hydrogen.

The method further comprises heating the growth cell by means of the heating device so that the swelling material sublimates and resublimates at the seed. Preferably, heating of the growth cell can be performed from radially all sides. For this purpose, the heating device may annularly surround the process chamber.

In providing the protective atmosphere in the interstitial space, it is preferred to set a positive pressure relative to an ambient pressure. For example, the overpressure in the protective container (containment vessel) may be set, further for example of at least 1 mbar above ambient pressure or more, preferably 3 mbar or more, more preferably 5 mbar or more above ambient pressure. When a positive pressure is set in the protective container relative to ambient, only insignificant or no gas from the ambient can enter the protective container. This ensures, for example, that no oxygen enters the protective container and-in the event of process gas being discharged into the protective container-a reaction could take place there.

The containment vessel is particularly easy to implement if it is constructed in such a way that it allows gas losses to the outside, especially to a small extent, i.e. it is only approximately gas-tight. This makes the design of the containment more cost-effective, since requirements for particularly high hermeticity do not have to be taken into account and yet no undesirable reactions of the reactive gas can occur outside the process chamber. For example, the containment can have an allowable leak rate that is greater than 0 l/min. Thus, it may be advantageous for cost reasons, and unproblematic, particularly due to the choice and geometry of the design, to allow a leak rate that is in the range 0≤leak rate≤5 l/min, or even in the range 0≤leak rate≤30 l/min. For example, the leak rate to be allowed may be greater than 2 ml/min, less preferably 5 ml/min, even less preferably 10 ml/min, even less preferably 50 ml/min, or even 100 ml/min. On the other hand, it does not make sense, for economic reasons and possibly those of workplace safety, to allow the leak rate of the containment to be too high. For example, it may be desired to limit the leak rate to less than 30 l/min, preferably 10 l/min, further preferably 4 l/min, still preferably 1 l/min, further preferably 500 ml/min, and still further preferably 150 ml/min. It is aimed to achieve leak rates in a range from 2 ml/min to 50 ml/min, preferably from 10 ml/min to 20 ml/min.

For example, the containment can have a total volume of more than 50 l, preferably more than 100 l, and/or a total volume of less than 500 l, preferably less than 250 l. In other words, a ratio of leakage rate to total volume can be set in the range of less than or equal to 1%, preferably less than or equal to 2%, more preferably less than or equal to 5% per minute.

To maintain the protective atmosphere, for example, inert gas can be supplied to compensate for gas losses and to build up and/or maintain an overpressure in the containment vessel. The overpressure prevents atmospheric oxygen from entering the containment from the outside. Thus, a relative overpressure in the containment vessel can be maintained by means of a pressure control system, for example in a range of 1 mbar above ambient pressure or more, preferably 3 mbar or more, more preferably from 5 mbar or more, to 50 mbar above ambient pressure or less, preferably 30 mbar or less. However, a completely gas-tight containment with a leakage rate of 0 ml/min or a leakage rate that is not measurably low is also basically encompassed by this, in which an overpressure can also be maintained in the containment.

To ensure that air is replaced from the containment vessel as completely as possible, the present description may further provide that a first inert gas is admitted into the containment vessel to flood the containment vessel. The first inert gas may be heavier than air, so that it is admitted into the lower region of the containment vessel, displacing the air upward. For this purpose, for example, a closable outlet at the upper end of the containment can remain open until the air has escaped.

Preferably, the protective atmosphere comprises an inert gas such as argon. Due to the high density of argon, it collects at the bottom of the containment vessel and slowly displaces the air upward without mixing with it. Other examples of protective atmosphere construction that are currently available in an economically feasible manner include xenon, nitrogen, or carbon dioxide. In principle, the protective atmosphere can include any fluid, whether individually or as a mixture, that is capable of providing a protective function in that it neutralizes the reactive gas in the event of excessive or unacceptable escape from the process chamber and/or prevents negative effects such as deflagration. The protective atmosphere can also exist, for example, under normal conditions of the standard atmosphere in the liquid or solid state.

When the air has been removed by the first inert gas, it can be replaced by another inert gas, for example a less expensive one. The present disclosure therefore further provides that after the containment vessel has been flooded once or several times with the first inert gas, the latter is replaced by the second inert gas, for example nitrogen.

In order to ensure that the reactive gas is not further introduced into the apparatus in the event of a rupture of the process chamber, it is provided that the containment vessel has a gas sensor which is able to detect the presence of reactive gas in the containment vessel. It can also be provided that the process gas supply to the process chamber is interrupted when the gas sensor detects the reactive gas in the containment vessel.

In a further development, the gas supply can be interrupted via a further pressure sensor or pressure switch, which monitors the pressure inside the process chamber, if a lower pressure is detected in the event of damage, such as a break in the quartz glass. For example, a drop below the absolute pressure to p≤980 mbar (abs), preferably to p≤950 mbar (abs), more preferably to p≤920 mbar (abs) can be detected for monitoring. The interruption of the reactive gas supply can thus also take place independently of the detection of reactive gas, such as hydrogen, in the space between the process chamber and the cooling jacket.

An opening of the process chamber, for example in the case of a fracture of the quartz glass, can be detected or indicated, for example, by one of the following criteria. Detection of the reactive gas/hydrogen can be carried out by a gas sensor in the containment vessel. In this case, the gas sensor is set up in particular to detect the process gas or a process gas content in the containment vessel. Alternatively or cumulatively, the overpressure in the containment p_{S} can be detected and, if the overpressure disappears, a process malfunction or a seal leak can be concluded (e.g. p_{S}<=approx. 2 mbar overpressure compared to atmosphere). This is possible if an (even low) overpressure relative to atmosphere is set in the containment, which is easy to detect. Such a vessel overpressure therefore also represents a safety criterion for the operation of the plant. A pressure test can therefore represent a step in a safety check of the plant.

A step in the process presented here can therefore be defined by a safety check of the containment vessel. Such a safety check can be realized by measuring the adjustable overpressure p_{S} in the containment. In other words, for example preparatory to the start of the production of the crystal, the containment can be checked with regard to the leakage rate or the tightness, so that if the leakage rate is too high, a safety state is assumed or indicated, i.e., for example, no operation is possible or a warning is generated.

Furthermore, alternatively or cumulatively, the pressure in the process chamber p_{P} can be measured, and as long as this pressure p_{P}≤950 mbar (abs), or p_{P}≤920 or, for example, p_{P}≤980, is maintained, no process disturbance is detected, whereas exceeding the pressure threshold can indicate a process disturbance. Also, alternatively or cumulatively, a sudden pressure surge/pressure rise in the process chamber (pressure rise rate greater than maximum possible or allowable pressure rise rate due to gases to be introduced) can be detected and indicate a process disturbance-such as a quartz glass breakage. The aforementioned criteria are advantageously independent of each other and can be used individually or in conjunction with each other to effect a shutdown of the process gas or hydrogen supply, and thus for example to ensure a safety standard of the apparatus. In other words, by means of the pressure measurement of pp before and/or during the process, it may be possible to detect more quickly whether process gas will enter or is entering the containment.

The containment can advantageously provide a cooling function. The cooling function can, for example, be designed so that a cooling medium, such as water, circulates around or through the containment. For example, the containment can have at least one cooling medium line for this purpose, through which the cooling medium flows. The at least one cooling medium line can be attached to the vessel wall of the containment vessel or at least be connected thereto in a thermally conductive manner, possibly with the aid of a thermally conductive paste. For example, the cooling medium line is soldered to the vessel wall. For example, the cooling medium line comprises copper, which is easy to process and/or is designed to be particularly thermally conductive.

The containment can be equipped to provide temperature control of the process conditions. For example, by means of the containment designed in this way, constant temperatures—or a similar temperature range—can be maintained at all times, irrespective of the ambient conditions, which may vary considerably. For example, the environment may include a daily temperature curve or even seasonal temperature fluctuations, or may also be influenced by possibly thermal processes taking place in the vicinity, whereby the advantageously designed containment vessel is able to keep these environmental conditions away from the process. Alternatively or cumulatively, the cooling function can also be influenced in response to the process parameters, such as the temperature in the process chamber, in order to effect a temperature control of the cultivation process. For example, the cooling medium flow rate through the at least one cooling medium conduit may be altered in response to ambient conditions and/or process parameters in order to alter heat removal. For example, when the environment and/or process temperature is warmer, more cooling medium can be deployed, and/or a colder cooling medium can be used, and/or an alternative cooling medium can be introduced.

The cooling medium line can be arranged on the outside of the vessel wall, preferably thermally conductively connected to the vessel wall or in any case arranged adjacent to the vessel wall. The cooling medium line can then cool the vessel wall and ensure that the heat quantity does not radiate into the immediate environment of the apparatus, but is carried away by the temperature control device. The outside arrangement of the cooling medium line has the advantage that fewer penetrations into the protective atmosphere or the inside of the containment vessel need to be provided, since the cooling fluid does not penetrate into the interior. For example, the vessel wall can be double-walled, i.e. have an inner wall and an outer wall, whereby the cooling medium line can be arranged between the inner wall and the outer wall of the vessel wall. Then the cooling medium line together with the fastenings for the cooling medium line is hidden from view and protected from mechanical damage. Since the temperature control unit is capable of dissipating a substantial part of the heat output from the process chamber, the outer wall of the vessel wall is subject to no or few restrictions with regard to material selection or protection against contact, since it does not become hot.

The present description also relates to an apparatus for the process-safe production of single crystals, such as by the PVT method, which comprises a process chamber for accommodating a highly heatable growth cell and a heating device for heating the growth cell. The process chamber has a process gas connection for filling it with a process gas which can be provided from a process gas source. The growth cell is prepared to receive a source material and a seed.

The apparatus comprises a containment vessel for enclosing the process chamber, preferably in a gas-tight or substantially gas-tight manner. For example, the containment vessel enables process-safe operation with a reactive gas as the process gas. The containment vessel has a vessel wall, such that an intermediate space is created between the vessel wall of the containment vessel and the process chamber, which is arranged such that the intermediate space can be flooded with a protective atmosphere. The process chamber is arranged within the containment vessel. Furthermore, the containment can have a connection to a protective gas source so that the intermediate space between the vessel wall of the containment and the process chamber can be flooded with protective gas, for example before the PVT process is carried out.

The vessel wall can be a segmented vessel wall enclosing the process chamber at least radially on all sides, the vessel wall comprising a plurality of at least two wall segments. By means of the segmented vessel wall, the outer wall of the containment can be formed for enclosing the process chamber, preferably in a gas-tight or essentially gas-tight manner. The vessel wall can comprise as wall segments, for example, a feed-through segment, a testing or inspection segment, a cooling segment, a lid segment, which can be designed for example in multiple parts, and/or a bottom segment.

The vessel wall is preferably designed to also enclose the process chamber from above and/or below. Preferably, the vessel wall can be designed to completely enclose the process chamber on all sides. However, this is not necessary in every case. For example, if the process chamber is recessed in a floor, a part or section of the process chamber can also be designed without a direct protective jacket in the form of the containment vessel, and the portion of the process chamber can be surrounded by the containment vessel that lies above the floor. In this way, the protective container can be designed as far as the floor and, if necessary, seal tightly there.

In a further embodiment, the vessel wall may include a process chamber adapter for accommodating different sized process chambers on the same vessel wall. Thus, the components of the vessel wall can be provided in one size or in a few sizes to cover a variety of different process chambers or process chamber sizes.

The vessel wall can be of double-walled design. The double-walled construction of the vessel wall can have design advantages or simply enable a pleasing exterior without components of the containment being visible from the outside.

For example, a cooling device can be arranged in an intermediate area of the double-walled vessel wall. This design has numerous advantages. For example, the cooling device itself is protected from the direct heat radiation of the process chamber and is concealed behind an inner wall of the vessel wall. In addition, the assembly of the cooling device is particularly simple in this case, since it can be attached to the inner wall of the vessel wall, for example by gluing, soldering or screwing it on there by means of connectors. An outer screen then covers the intermediate area so that it is protected from external interference or unintentional damage, which is particularly advantageous if the cooling device is located there.

The containment vessel may be constructed to allow gas to escape to the outside. It can have a pressure sensor, whereby the pressure sensor is signal-connected to a control device and the control device is designed in such a way that an overpressure is set in the containment (relative to the environment or atmosphere) on the basis of the pressure sensor signals.

The pressure sensor can also comprise a pressure switch or be formed from a pressure switch. For example, the pressure sensor can be formed by a differential pressure switch that measures the pressure difference between inerting in the containment and the atmosphere or environment. If necessary, the pressure sensor can then trigger a circuit when the pressure exceeds or falls below an adjustable pressure difference, for example as a safety circuit or shut-off.

With regard to the orientation of the installation of the apparatus, it can be advantageous if an inert gas connection is located in the lower area of the containment and a closable outlet is located in its upper area. This allows the air in the containment to be completely displaced by the inert gas flowing in at the bottom to the top of the outlet, where it leaves the containment.

The containment vessel preferably has two inert gas connections for two different inert gases. After the first inert gas has removed the air from the containment vessel, a low-cost fluid, such as nitrogen, can be filled in as a second fluid via the second inert gas connection, thus replacing the first inert gas.

The containment vessel preferably has a gas sensor that responds to a reactive gas. In this way, it can be determined that reactive gas (e.g. hydrogen) has entered the containment vessel, for example in the event of a rupture of the process chamber.

As already mentioned above, the apparatus can be used for example to produce SiC single crystals by the PVT process. For this purpose, the growth cell is equipped with a Si silicon carbide as the source material and the process chamber can be flooded with hydrogen as a reactive gas in addition to other process gases (e.g., argon).

In a further embodiment, the apparatus may further comprise a support frame for holding at least two wall segments to the support frame. In this case, the vessel wall is thus segmented and has the at least two wall segments. Together, the wall segments form the vessel wall. For example, one wall segment may be provided as a fixed wall segment and another wall segment may be designed to be detachably connected so that it is easily removable.

The support frame thus forms a retaining structure for receiving the wall segments on the support frame, so that the support frame and wall segments together form the vessel wall of the containment vessel (8), for enclosing the process chamber preferably in a gas-tight or essentially gas-tight manner.

At least one sealing element may be arranged on or in the support frame for sealing the support frame from the plurality of at least two vessel segments and/or for sealing the containment vessel from the environment. In other words, the support frame may be designed to be sealed to reduce gas leakage from the containment vessel to the environment.

Alternatively or cumulatively, one or a plurality of wall segments may have a correspondingly formed seal receptacle. In other words, the sealing element may be arranged on the wall segment. Such a sealing receptacle may be formed as a material bead or rim against which the sealing element may be placed or inserted. Typically, in such an arrangement, the sealing element would preferably be adhered by means of an adhesive. Alternatively, the wall segment could be designed with a greater material thickness so that a groove could be provided for the sealing element, whereby it may have to be taken into account that this may increase the costs for a respective wall segment. It may also be more difficult to handle if it is heavier due to a greater material thickness.

Particular advantages are achieved by combining the multi-part containment with the sealing elements, since this makes it possible to use common construction materials, such as metal or steel for the wall elements, and yet still achieve a sufficient overall tightness of the containment. In an environment where core temperatures of over 2000° C. occur, however, such a design poses some challenges that could be solved with amazing ease using the embodiments explained with the present description and the embodiment examples.

The support frame preferably has at least one longitudinal groove on an outer side for receiving a sealing element. In other words, the sealing element is drawn into the longitudinal groove of the support frame. In this case, the longitudinal groove can be formed as a retaining groove. The advantage of a retaining groove is that the sealing element is held securely in the retaining groove and can only be removed there, for example, by applying a jump-over force. In the present case, the use of a trapezoidal groove as a retaining groove is possible because the sealing elements can be reused several times and can remain in such a retaining groove. The sealing elements can be designed as O-rings or in the form of lip seals.

The protected installation of the sealing elements as described here ensures that the sealing elements do not burn or age rapidly in the extremely thermally hot environment. For example, the sealing elements are arranged to be protected from radiant heat. This arrangement in turn synergistically enables the use of permanently reusable materials for the sealing elements. Since, in turn, the sealing elements are permanently reusable and are not destroyed by operation, they can again be advantageously arranged in a retaining groove, which in the final analysis further simplifies the handling of the containment (in this case when assembling the wall segments with the support frame). In this way, the sealing elements are protected from dirt and damage and remain in the advantageous holding grooves in the protected installation position in which they are protected from the radiant heat during operation.

Alternatively or adapted to the situation of the at least one sealing element on the supporting frame, at least one wall segment can have the seal receptacle, i.e. a special shaping, for fastening a sealing element against the supporting frame, as described above. For this purpose, an edge of a wall segment may be externally overlaid with respect to the edge of the supporting frame and a sealing element may be attached to the edge projection. Another embodiment provides a longitudinal groove on the narrow side for receiving a sealing element. In this case, the wall segment may have a greater overall wall thickness or wall reinforcement at least in the vicinity of the edge.

The support frame may be configured to receive a segment seal, and/or to receive a cover seal, and/or to receive a bottom seal. In other words, the support frame can be designed to accommodate one or more seals with different purposes.

The support frame can be sealed against a base plate, for example by means of a base seal. The support frame can be sealed alternatively or cumulatively with respect to the adapter, for example by means of an adapter seal. The support frame can be sealed alternatively or cumulatively with respect to the vessel segments, for example by means of a segment seal.

Each vessel segment can be assigned an individual circumferential segment seal. For example, if four vessel segments are used, four separate segment seals can be provided so that the vessel segments are sealed individually. Indeed, it has been shown that it is advantageous if the vessel segments are not in electrical connection with one another. However, if they are made of electrically conductive material-which is also preferred, since the vessel segments are to be thermally conductive and inexpensive materials exist that are thermally and electrically conductive-then it may be expedient to electrically insulate the vessel segments from one another. This is particularly the case if inductive heating is used. The insulation can be provided by means of the connection via the support frame so that the vessel segments can be mounted at a distance from one another. In this case, it is advantageous if each vessel segment is assigned its own segment seal which, if necessary, assumes the insulating function.

The support frame can be constructed in several parts. The support frame may comprise a plurality of at least two frame elements releasably attachable to each other. The support frame may alternatively or cumulatively comprise at least one of a ceiling element, a plurality of bar elements, that are preferably vertically arranged, and/or a base floor element. The multi-part structure of the support frame simplifies the overall setup of the apparatus, and may also help to further reduce the cost of the apparatus. In addition, the multi-part design of the support frame offers advantages for any maintenance work that may be required and/or for replacing the process chamber when a crystal has finished growing and the same containment is to be used to protect another process chamber or another growth process.

In other words, the containment vessel is designed to be reusable, and can be used to produce a large number of crystals using the PVT process, which can lead to considerable savings, particularly on the cost side. The containment vessel can be built up modularly around the process chamber before a growth process is carried out, and can be dismantled again in a simple manner after the crystal growth has been carried out. In a particularly advantageous embodiment, all parts can be reused, so that the containment can again be built up modularly around the new process chamber before carrying out another growth process. The multi-part design means that the containment can be easily and effortlessly assembled around a further process chamber and a safety atmosphere can be provided.

The support frame elements can also be designed to be sealed against each other so that no or only little inert gas escapes into the environment even between the contact or tangency areas between individual support frame elements. Alternatively or cumulatively, a frame seal may be included for sealing one frame member against a second frame member. The frame seal can, for example, be arranged in a frame seal plane that is not arranged in the same plane as the segment seal.

For example, one embodiment may be such that each segment seal passes through the cover element, through two rod elements, and through the bottom element. Alternatively or cumulatively, a lid seal may be disposed on an upper surface of the lid element for sealing the lid. Further alternatively or cumulatively, a bottom seal may be arranged on a bottom side of the bottom element for sealing the bottom element with respect to the bottom. The bottom may be provided as a manufacturing part or as a mounting plate.

The cover element can have a segmental sealing groove on the segment side. The rod elements can each have at least one segmental sealing groove, preferably two segmental sealing grooves per rod element. The floor element or elements may have a segmental sealing groove. For example, at least one of the segment sealing grooves of one of the rod elements can be designed to be aligned with the segment sealing groove of the cover element and the segment sealing groove of the base element, so that a segment seal can be inserted into the mutually aligned segment sealing grooves for circumferential sealing of the wall segment.

Furthermore, the apparatus may comprise a support frame for holding at least two wall segments to the support frame. The support frame may be of multi-part construction. Alternatively or cumulatively, the support frame may comprise a plurality of at least two frame members releasably attachable to each other. Alternatively or cumulatively, the support frame may comprise at least one of a ceiling element, a plurality of, for example vertical, rod elements, and/or a floor element.

The support frame can have at least one longitudinal groove on an outer side for receiving a sealing element. Alternatively or cumulatively, the support frame can be designed to accommodate a segment seal, and/or to accommodate a cover seal, and/or to accommodate a bottom seal. Alternatively or cumulatively, the cover element may be integrally formed, for example for mounting on the rod elements.

Alternatively or cumulatively, the cover element may be connected to the bottom element via the rod elements. Alternatively or cumulatively, the elements of the support frame can be detachably connected to one another, for example screw-connected, in order to provide a stable structure on the one hand, which can be dismantled on the other hand, for example for maintenance or opening purposes.

The floor element can be designed in several parts and have floor fastening sections and intermediate sections and be prepared in such a way that the rod elements can be placed between the floor fastening sections and on the intermediate sections. Alternatively or cumulatively, the floor element can be designed in one part and the rod elements may be insertable into recesses of the floor element. Alternatively or cumulatively, the cover element may be formed in one piece and the rod elements may be insertable into recesses of the cover element. Further alternatively or cumulatively, the cover element can form a laterally projecting collar so that the wall elements can be fitted below the cover element without the wall elements projecting laterally beyond the cover element.

The support frame can be designed as an electrical insulator. This ensures that the wall segments are electrically insulated from each other. Alternatively or cumulatively, the support frame can be non-magnetic. This can ensure that the wall segments cannot form a ring magnet, which can possibly interfere with the heating device. Further alternatively or cumulatively, the support frame may be formed of temperature resistant material. Further alternatively or cumulatively, the support frame may be formed of thermally and/or electrically non-conductive material. Further alternatively or cumulatively, the support frame may comprise or consist of ceramic, plastic, or a composite material or a combination thereof.

The support frame can preferably form a retaining structure for receiving the wall segments on the support frame, so that the support frame and wall segments together form the vessel wall of a containment vessel, for enclosing the process chamber preferably in a gas-tight or essentially gas-tight manner. An intermediate space may be created between the vessel wall of the containment vessel and the process chamber, which is arranged such that the intermediate space can be flooded with a protective atmosphere. Alternatively or cumulatively, the containment vessel may enclose the process chamber on all sides.

The heating device can be designed to surround the process chamber. Alternatively or cumulatively, the heating device can be formed annularly around the process chamber.

In the following, the present disclosure will be described in more detail by means of embodiment examples and with reference to the figures, whereby the same and similar elements are partially provided with the same reference signs and the features of the various embodiment examples can be combined with each other.

### BRIEF DESCRIPTION OF THE FIGURES

It shows:

FIG. 1 Cross-sectional view of an apparatus according to the present disclosure,

FIG. 2 perspective and simplified view of a partially assembled containment vessel,

FIG. 3 perspective sectional view of an embodiment of an apparatus,

FIG. 4 exploded view of an embodiment of an apparatus,

FIG. 5 design of a support frame,

FIG. 6 detailed section of an embodiment of a support frame,

FIG. 7 further detail of an embodiment of a support frame,

FIG. 8 another detail of an embodiment of a support frame,

FIG. 9 detail of the path of seals in the supporting frame,

FIG. 10 further detail of the path of seals in the supporting frame,

FIG. 11 cross-sectional detail of an apparatus,

FIG. 12 partially assembled containment with support frame,

FIG. 13 design of an illustrative segment of a double-walled vessel wall with temperature control unit,

FIG. 14 detail of a connection of the temperature control unit,

FIG. 15 design of a cooling segment of the vessel wall with part of the temperature control device,

FIG. 16 perspective view of an embodiment of a containment vessel,

FIG. 17 perspective partially opened view of an embodiment of an apparatus with process chamber,

FIG. 18 perspective view of an apparatus.

### DETAILED DESCRIPTION

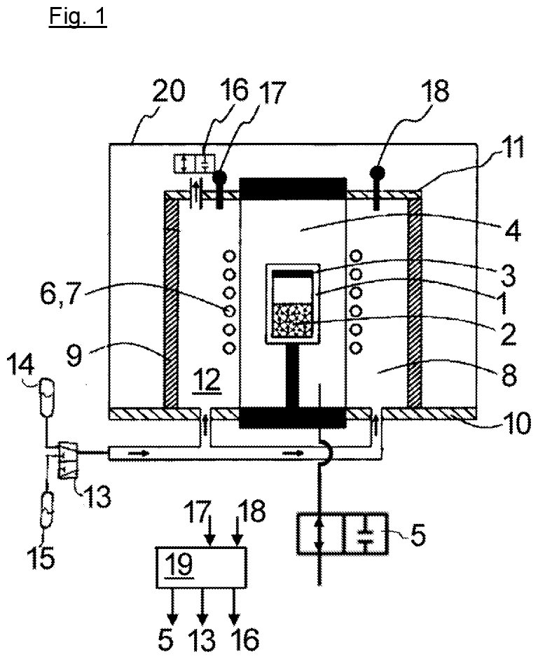

FIG. 1 shows a cross-sectional view of an embodiment of the apparatus. In the center of the apparatus, standing on a stand, is a growth cell 1 consisting of a hollow cylinder with a bottom and a lid closing the two ends of the hollow cylinder. The growth cell 1 is made of a porous graphite. A swelling material 2 is layered on the bottom. On the reverse side of the lid is a seed 3.

The growth cell 1 is arranged in a process chamber 4 which comprises or consists of a hollow cylinder closed at both ends by a floor or a ceiling. The cylindrical wall of the process chamber 4 comprises or consists of a heat-resistant quartz glass and can be filled with a process gas via a process gas connection with an inlet valve 5. Since the graphite of the growth cell 1 is porous, the process gas from the process chamber 4 also enters the growth cell 1.

A heating device 6 comprises or consists of an induction coil 7 which surrounds the process chamber 4 at the level of the growth cell. When an electric current flows through it generates an electromagnetic field which induces an electrical current in the graphite of the growth cell 1, heating the growth cell 1 to over 2,000° C. up to 2,400° C.

The high temperatures and the permeability for the electromagnetic field of the induction coil 7 make it necessary to manufacture at least the cylindrical wall of the process chamber 4 from a temperature-resistant material suitable for this purpose. Usually, the cylindrical wall of the process chamber 4 is made of quartz glass, which has proven to be particularly suitable and inexpensive to manufacture.

To produce a SiC single crystal, silicon carbide is added to the growth cell 1 and the process chamber 4 is flooded with a process gas. The process gas can comprise a reactive gas, such as containing a proportion of hydrogen, and/or be composed of up to 100% of hydrogen. If the growth cell 1 is now heated by means of the induction coil 7, the silicon carbide sublimates and accumulates layer by layer on the seed 3, so that a SiC single crystal grows. If hydrogen is used in the process gas, it can ensure that no crystal defects are formed in the crystal in the process or that foreign atoms could be deposited at the respective growth site. An incorporation of undesirable foreign atoms regularly leads to a change in the electrical conductivity, which can also occur locally if necessary and can be detrimental as a disturbance or reduction in quality. The process gas composition can also be influenced by reactions with other process gases or the hot zone (graphite components) through the use of the reactive gas. The changed process gas composition can in turn influence the crystallinity, structure, crystal defects and doping of the SiC crystal.

For example, it could be shown that beneficial effects are achieved from a hydrogen content of 5% or more in the process gas, whereby in such low concentrations of less than 5% hydrogen in the process gas typically no protective measures are necessary, for example for explosion protection. Particularly advantageous results were obtained in the range between 5% hydrogen content and about 40% hydrogen content, with an increased degree of purity of the crystal being obtained in the range of 15% hydrogen content in the process gas (preferably ±5%). In principle, however, the use of a containment according to the present disclosure is also advantageous at low concentrations.

However, the use of a reactive gas such as hydrogen is problematic, as described above, because in the event of a potential rupture of the wall of the process chamber 4, the reactive gas mixes with the ambient air—without the containment vessel described here—so that, for example, an ignitable gas mixture can be produced which would immediately ignite on the hot parts of the apparatus.

The process chamber 4 of the embodiment shown here is surrounded by a containment vessel 8 comprising a cylindrical vessel wall 9 surrounding the cylindrical wall of the process chamber 4, the vessel wall 9 standing on a floor 10 and being closed at the top by a lid, cover, or ceiling 11. The floor 10 and ceiling 11 of the containment 8 adjoin the bottom and ceiling of the process chamber 4.

The containment 8 can at the same time be part of the cooling concept of the apparatus. In other words, the containment 8 can be integrated into the cooling concept of the apparatus. For this purpose, the cylindrical vessel wall 9 can be provided with cooling channels that are connected to a cooling system. The cooling concept may thus provide that the containment 8 provides a cooling function for the apparatus. For example, a cooling medium may circulate through the containment 8, such as water. On the other hand, it may be provided that the containment atmosphere in the containment 8 provides the cooling function. For example, the containment atmosphere can be circulated for this purpose in order to dissipate heat output. Overall, the containment can be equipped in such a way that the containment with its cooling function can be used to control the temperature of the process conditions, so that constant temperatures—or a similar temperature range—can be maintained, regardless of the ambient conditions, which may vary considerably. For example, the environment may include a daily temperature curve or seasonal temperature fluctuations, or may also be influenced by any thermal processes taking place in the vicinity.

Finally, the containment 8 can be constructed in such a way that it is metallically conductive. The metallically conductive containment 8 can provide shielding for the process taking place inside in the manner of a Faraday cage, so that, for example, electromagnetic alternating fields in the vessel wall 9 of the containment 8 are given a defined end point and do not run out asymptotically, potentially to infinity. This can be advantageous if several apparatuses are to be set up next to each other, in which case corresponding alternating fields can influence each other and interfere with each other's process conditions. In other words, the metallically conductive containment 8 can ensure uniform process conditions even under the condition that several apparatuses, possibly also of different types, can be set up close to each other without the processes interfering with each other.

Overall, it can be seen that the containment 8 is capable of solving several tasks at once in a synergistic manner. Not only that it is able to provide the mentioned protective atmosphere, which enables the application of a reactive gas in the process chamber. In addition, the containment 8 is able to shield the process chamber from various ambient conditions such as temperature fluctuations or fluctuating electrical and/or magnetic fields and thus ensure uniform process conditions for the process taking place in the process chamber.

In the bottom of the containment vessel 8, a ring line with one or more connections can be arranged at an annular space or interspace 12 between the vessel wall 9 of the containment vessel 8 and the cylindrical wall of the process chamber 4 consisting of a quartz glass. The ring line is connected to an argon source 14 and to a nitrogen source 15 via a shuttle valve 13.

A closable exhaust or outlet valve 16 is located in the ceiling 11 of the containment 8. A gas sensor 17 (for example as a hydrogen sensor) and a pressure sensor 18 are also provided there.

The entire apparatus may be covered by a hood 20 made of an unbreakable plastic or sheet metal, which rests on the bottom of the containment vessel 8.

Furthermore, a control device 19 is provided, which is signal-connected to both sensors 17, 18 and controls the shuttle valve 13, the outlet valve 16 and the inlet valve 5 for hydrogen supply via control lines.

The control device 19 allows the following procedures to be performed: Filling the containment 8 with an inert gas before the process chamber 4 is filled with hydrogen:
(1) The outlet valve 16 is opened.
(2) The shuttle valve 13 is switched so that argon gas from the argon source 14 flows slowly into the interspace 12 from below, so that the interspace 12 fills with the argon gas from below, the air present being displaced by the open outlet valve 16 (or pressure relief valve or the like).
(3) Closing of the outlet valve 16 and the shuttle valve 13.
(4) Observing a filling pause so that any residual air from the argon gas can settle upwards.
(5) If necessary, repeating steps (1) to (3) once or several times.
(6) Opening of the outlet valve 16.
(7) Switching the shuttle valve 13 so that nitrogen gas slowly flows into the interspace 12 from below, filling the interspace 12 from below with the nitrogen gas from the nitrogen source 15 and displacing the argon gas present through the open outlet valve 16.
(8) Closing of the outlet valve 16.
(9) Setting and maintaining an overpressure in the interspace 12 by controlled opening of the shuttle valve 13 so that no air can flow into the interspace 12 despite existing and accepted leaks in the containment vessel.

Sufficient overpressure is approx. 2 mbar above ambient pressure.

In any case, steps (1) to (3) and (9) are carried out. Steps (4) and (6) to (8) are optional.

In order to be able to check whether the interspace 12 is free of oxygen to a sufficient extent, an additional oxygen sensor can be provided.

Behavior in case of breakage of the glass wall in operation:
(1) Constant monitoring of the gas sensor 17 and
(2) Shutting off the hydrogen supply when the gas sensor 17 detects hydrogen in the interspace 12.

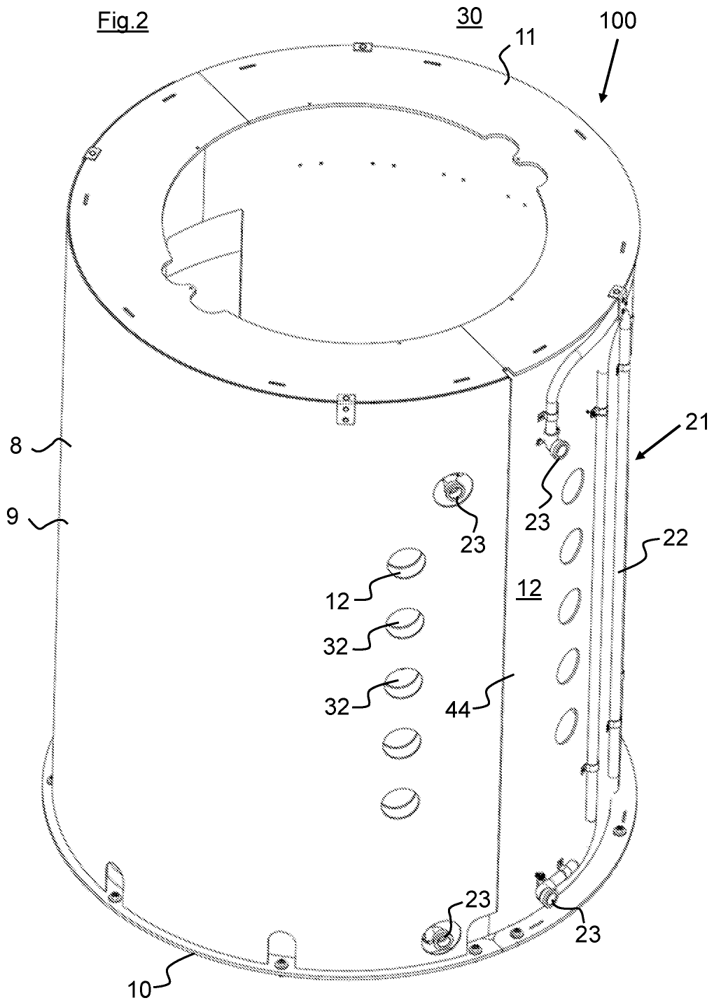

With reference to FIG. 2, a perspective view of a simplified embodiment of a partially assembled containment 8 is shown, whereby for reasons of clarity various add-on parts as well as also the process chamber 4 are not shown. Furthermore, for the sake of completeness, it should be noted that the embodiment shown with FIG. 2 has no details for sealing the interspace 12, so that the leakage rates achievable with this embodiment would be comparatively high. Improved sealed containment vessels 8 are presented with embodiments of the further figures.

In FIG. 2, a temperature control device 21 is arranged, at least partially, in the containment 8, whereby a fluid can be fed into a coolant line 22 through connection pieces 23. The coolant line 22 can be connected to the inner wall 44 of the containment vessel 8, for example glued, soldered, welded or screwed thereto. From the process chamber 4, heat power reaches the inner wall 44 predominantly as radiant heat, from where the heat power can be efficiently dissipated by means of the temperature control device 21. For example, liquid water can be used as a coolant. The amount of heat that can be dissipated by the temperature control device 21 can preferably be adjustable. For example, the amount of heat that can be dissipated can be influenced via the temperature specification for the coolant and/or throughput quantity or speed, i.e. a temperature control can be provided. Then, in response to sensor signals measuring the ambient temperature and/or the process temperature, a temperature control of the process chamber 4 can be achieved with the temperature control, so that a substantially constant temperature is present in the process chamber 4 during the process cycle.

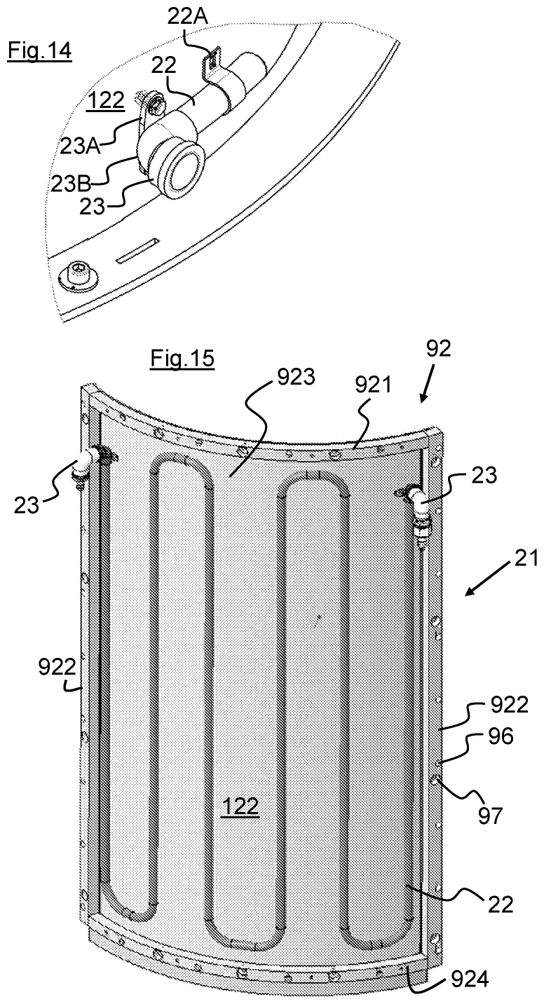

The containment 8 has sight glasses 32 which bridge the interspace 12 and allow a view of the process chamber 4, for example for the purpose of process monitoring. In order to keep the direct heat radiation small, the sight glasses 32 are designed to be relatively small. Furthermore, FIG. 14 shows a detail of the coolant line 22 with line attachment 22A, connection piece 23, transition piece 23B and connection piece attachment 23A.

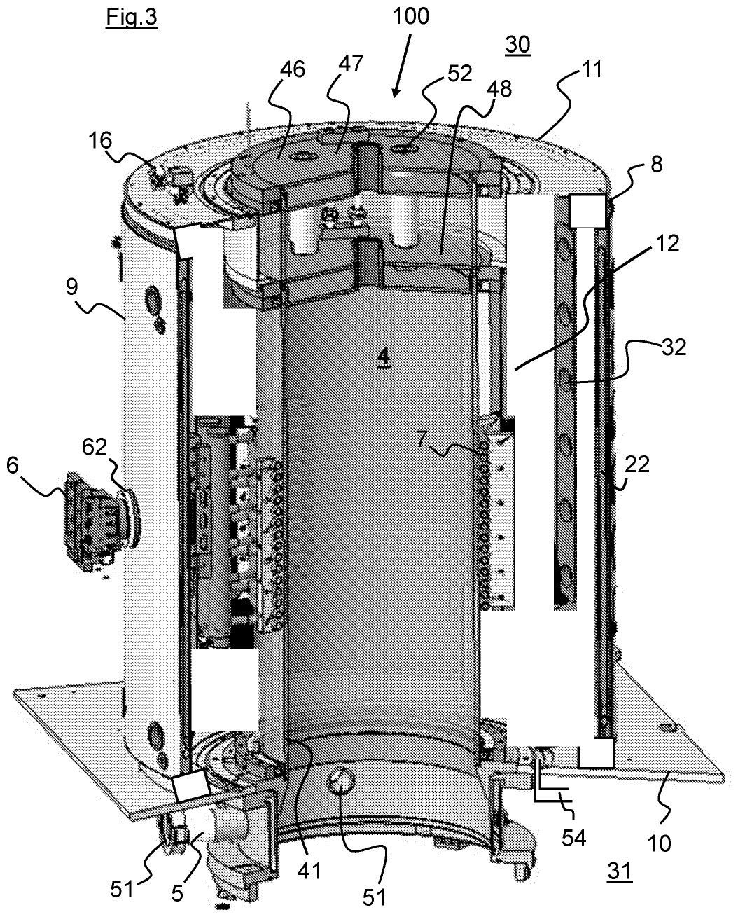

FIG. 3 shows a sectional view of an embodiment of an apparatus 100. A process chamber 4 is partially surrounded by an induction coil 7, which is supplied with electrical power by a heating device 6. The heating device 6 is partially arranged inside and outside the containment 8, and for example the power electronics may be arranged outside, so that a sealed feedthrough is provided to reduce gas leakage. The induction coil 7 with parts of the electronics is in the interspace 12, i.e. in the space that can be occupied by the containment atmosphere.

The inert gas can be supplied through the inert gas supply 54 on the underside of the interspace 12 (several inert gas supplies 54 may be provided). The outlet valve 16 is arranged on the ceiling 11, by means of which, for example, the external air (containing oxygen) initially arranged in the protective container 8 can be let out of the protective container 8, for example by letting in a protective gas which is heavier than air. Subsequently, if a connection line is connected to the outlet valve 16 (not shown), circulation of the protective gas can also be provided, for example to remove heat quantity from the protective container 8, or to ensure a regular exchange of the protective gas.

In the case shown here, the coolant line 22 of the temperature control device 21 is arranged in the vessel wall 9, which is of double-walled design. In the cross-section of the containment 8 with process chamber 4 shown with FIG. 3, the interspace 12 of the containment 8 for receiving the protective atmosphere extends from the chamber wall 41 and, for example, all the way around the process chamber 4 to the vessel wall 9, the interspace 12 being designed to be sealed against the vessel wall 9 in order to keep the gas leakage rate from the interspace 12 into the environment 30 low.

Furthermore, the embodiment shown with FIG. 3 shows a special feature in that the process chamber 4 is equipped with an adapter 46. In the embodiment shown, the adapter 46 has two alternative upper covers 47, 48 so that, depending on the desired process height, the upper cover 47 or the upper cover 48 lying further inwards can be used. The covers 47, 48 can thus be used alternatively to each other, if necessary.

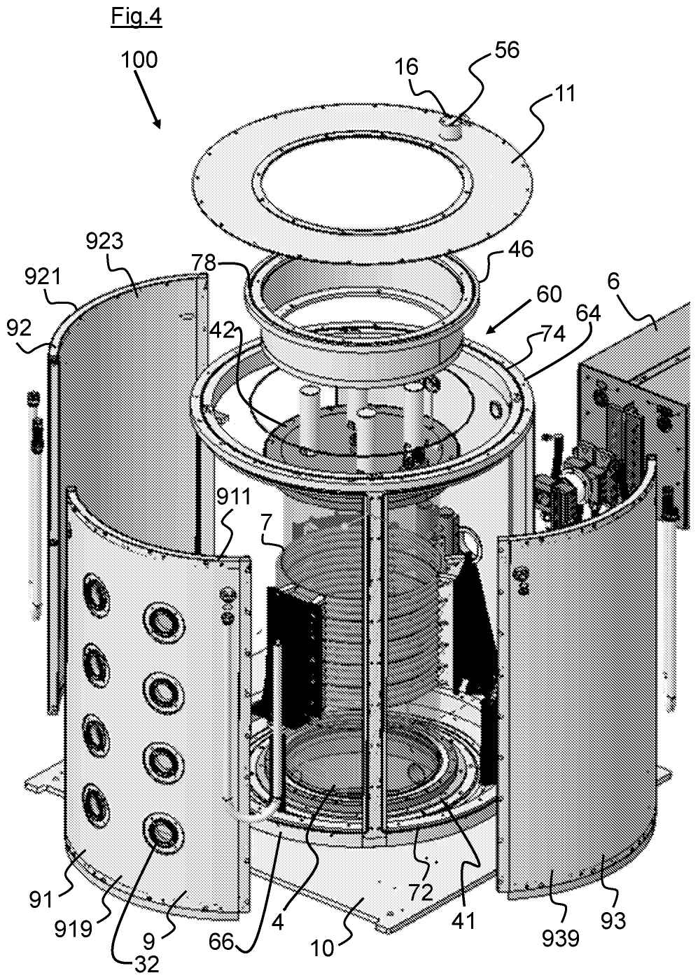

With reference to FIG. 4, an apparatus 100 is shown in exploded view in that the components of the containment 8 used there are visible. Inside, the process chamber 4 is arranged, in this embodiment in an empty version for better illustration. The quartz glass enclosure 41 (process chamber wall) forms the inner end of the interspace 12, which is arranged between the quartz glass enclosure 41 (as the inner wall of the containment vessel) and the vessel wall 9. The induction coil 7 serves as a heater and is arranged annularly around the process chamber 4.

The process chamber wall 41 is initially open at the top, with the process chamber 4 being closed off or sealed by means of a chamber closure 42. The upper closure is formed by the adapter 46, which engages in the process chamber wall 41 in a dual function and seals the containment 8 in the upper region towards the inside and towards the ceiling 11. Via the ceiling 11, the adapter 46 is connected to an upper frame end or cover element 64 of the support frame 60. The support frame 60 forms the “skeleton” of the containment 8, so to speak, in that numerous components of the containment 8 can be attached to the support frame 60, such as the wall segments 91, 92, 93 and the ceiling 11. The support frame 60 is in turn attached to the floor 10 via a base element or lower frame end 66, so that a stable and rigid construction is formed overall.

In the embodiment shown in FIG. 4, an inspection segment 91 can be mounted on the support frame 60, comprising one or more inspection glasses 32 for viewing the process chamber 4 or the process taking place therein. Furthermore, the two cooling wall segments 92, 93 shown here can be arranged on the support frame 60. In the rear area, the electronic unit of the heating device 6 is shown, which can be arranged outside the containment 8 and the connections to the induction coil 7 are carried out with bushings (cf. e.g. FIG. 7) through the vessel wall 9. To improve sealing, the support frame has a plurality of seals, here visibly segment seals 72, a cover seal 74 and an adapter seal 78. The wall segments 91, 92, 93 shown in FIG. 4 are of double-walled design and each have an inner wall (recognizably the inner wall 923 of the cooling wall segment 92) and an outer panel 919, 939.

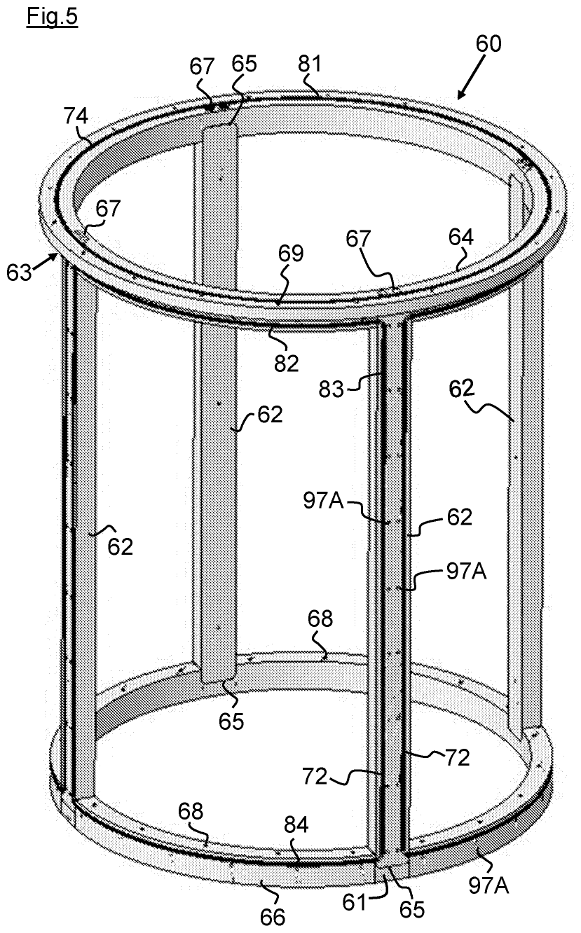

Referring to FIG. 5, a multi-part support frame 60 is shown, which, as a whole, forms the support frame 60 for supporting the wall segments 91, 92, 93, 94. The support frame 60 has a bottom element or lower frame end 66, which can be formed in one piece or in multiple pieces. In the case shown here, the lower frame end 66 is multi-part, so that a plurality of four bottom elements together with four intermediate pieces 61 form the lower frame end 66 as a whole. A receiving groove 84 is provided on the segment side of the lower frame end 66 to receive the segment seal 72. The segment seal 72 runs through the floor element receiving groove 84, through the rod element receiving groove 83 and through the cover element receiving groove 82 and is thus designed to provide a circumferential seal around a wall segment. A cover seal receiving groove 81 is provided on the upper side of the cover element 64 to receive the circumferential cover seal 74. All the sealing elements shown have in common that they are arranged on the segment side of the support frame 60 and are thus protected from the heat radiation of the process chamber 4 by the support frame 60.

The support frame 60 is preferably made of electrically and/or thermally non-conductive material. If the segments 91, 92, 93, 94 or the ceiling 11 are fastened to the support frame 60, for example in the mating fasteners 97A or 69 (screw holes) then a distance between the wall segments 91, 92, 93, 94 and the ceiling 11 can be set by means of the support frame 60 so that the planar components of the containment vessel 8 do not touch each other. Thus, the planar components of the containment vessel 8 can be electrically isolated from each other when they are not in contact and the support frame 60 is not electrically conductive. Nevertheless, a good sealing of the containment 8 can be realized by means of the provided receiving grooves 81, 82, 83, 84 and the seals 72, 74, 76, 78, because the segments 11, 91, 92, 93, 94 can be sealed against the supporting frame 60. If necessary, this offers the advantage of providing the segments 11, 91, 92, 93, 94 of comparatively inexpensive raw material such as steel or other metals which have excellent thermal conductivity, but without forming a closed metallic or conductive containment into which the alternating electromagnetic fields of the induction heater 6, 7 could play and interfere with the heating operation or even make it impossible. In order to further separate the wall segments 91, 92, 93, 94 from the ceiling 11, the upper frame termination 64 has a recess 63 over which the upper frame end or cover element 64 forms an overhang so that the cover element 64 is, for example, flush on the outside with the outer panels 99, 919, 929, 939 of the wall segments 91, 92, 93, 94. This ensures that the wall segments 91, 92, 93, 94 do not form an electrical short circuit via the ceiling 11. In addition, the protrusion further simplifies assembly of the ceiling 11 and forms a wider support surface for the ceiling 11, further improving sealing and providing further increased stability overall for the frame 60.

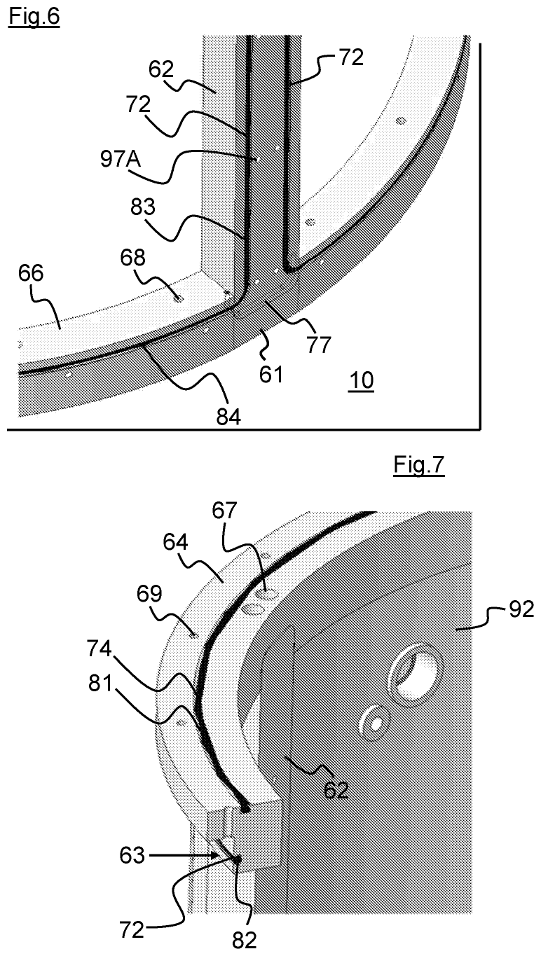

Referring to FIGS. 6 to 10, detailed sections of various embodiments of the support frame 60 are shown. With FIG. 6, the transition from the lower frame end 66 to the floor 10 is shown more clearly, wherein the segment seal 72 is inserted into the floor element receiving groove 84 and the flush adjoining rod element receiving groove 83. The lower frame section element 66 has connecting means 68, for example screw holes for inserting fastening screws for fastening the lower frame end 66 to the floor 10. A frame part seal 77 is provided for sealing the rod element 62 against the intermediate piece 61 and at the same time against the lower frame ends 66.

FIG. 7 shows a detail of the upper frame end 64 with a rod element 62 and the wall segment 92 mounted thereon. The cover element 64 has recesses 67, in this case two screw holes for the insertion of screws for connecting the cover element 64 to the rod element 62. The recessed mounting of the screws in the recesses 67 enables the ceiling 11 to be mounted flush and thus in a sealing manner on the upper frame end 64. Also visible in profile is the recess 63 on the cover element 64, with the path of the segment seal 72 extending in the recess 63 also shown in the cover element receiving groove 82.

With FIG. 8, another detailed view of a section of a support frame 60 is shown, wherein a continuous lower frame end 66 rests on the floor 10 and is sealed against the floor 10 by means of the floor seal 76. The floor seal 76 extends in the receiving groove 85, and a plurality of screw holes 69 are provided for the passage of screw means for connecting the lower frame end 66 to the floor 10. In this regard, the use of recesses may not be necessary, since in the embodiment shown here no sealing surface is formed on the upper side of the lower frame end 66.

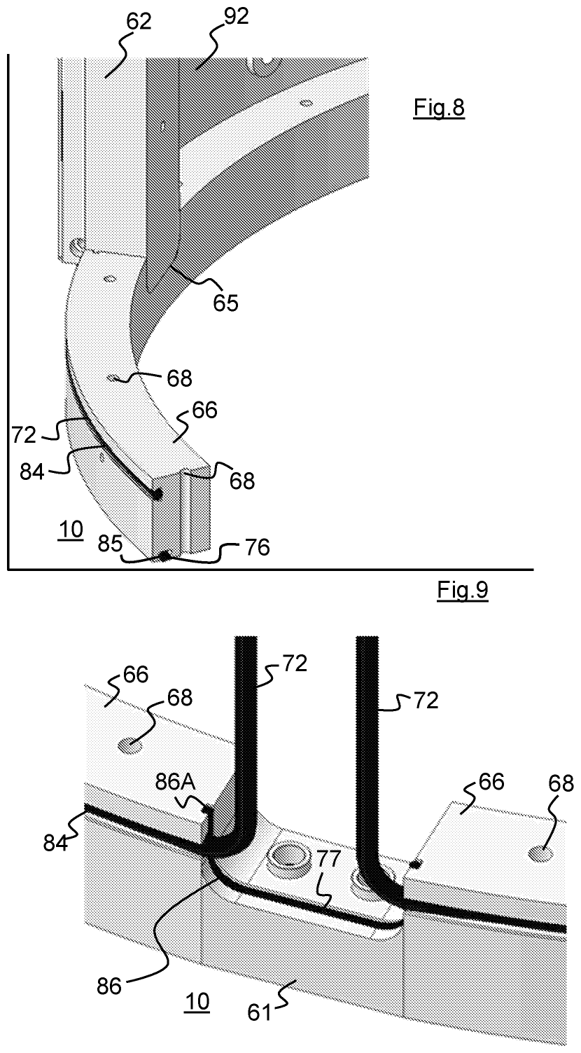

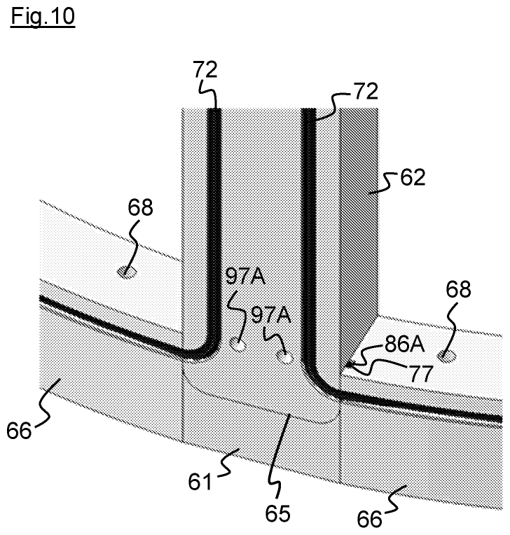

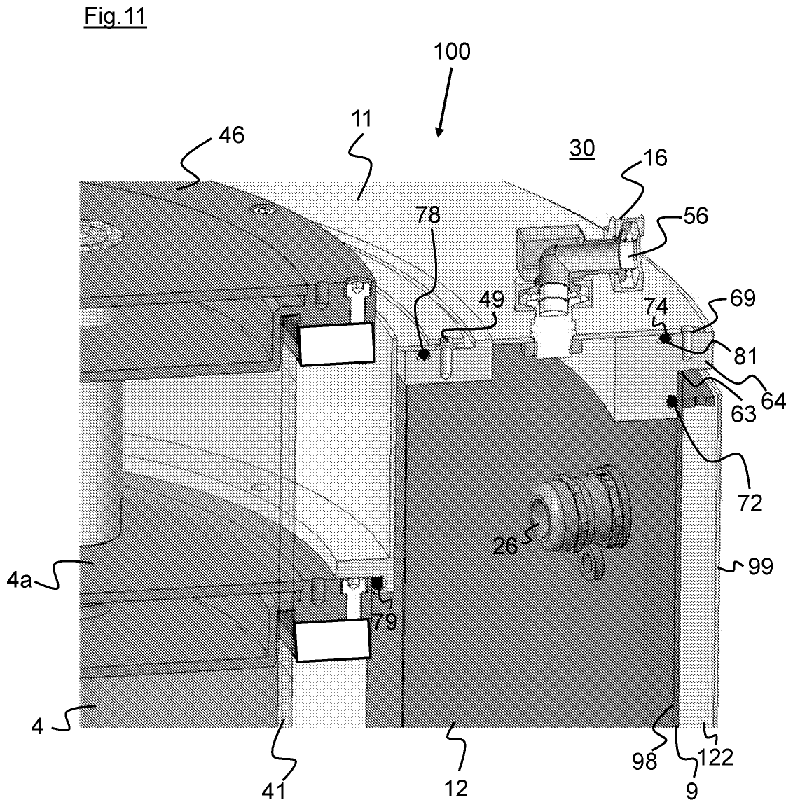

FIGS. 9 and 10 illustrate, in the case of a multi-part lower frame end 66 with intermediate piece 61, the connection of a rod element 62 (not shown in FIG. 9 for the sake of clarity, cf. e.g., FIG. 8 or 10) to the intermediate piece 61 and the sealing of the rod element 62 by means of the internal frame part seal 77 with respect to both the intermediate piece 61 and the multi-part lower frame end 66. To accommodate the internal frame part seal 77, a groove 86A is provided alongside each of two lower frame ends 66 and a groove 86 is provided in the intermediate piece 61 to accommodate the frame part seal 77 together. The rod element 62 abuts the intermediate piece 61 and two of the lower frame ends 66 at the sealed frame section joint 65. Mating fasteners 97A are provided in the rod element 62 for fastening one of the wall segments 91, 92, 93, 94 each.

Referring to FIG. 11, a sectional view of a cross-section through one embodiment of the apparatus 100 is shown. The adapter 46 forms the top closure of the process chamber 4 or 4a, and in this embodiment two process chamber heights of different process chambers 4 or 4a are shown by way of example, which can alternatively be closed off by the adapter 46. Thus, the adapter 46 can be sealed against the containment chamber 8 either via the adapter seal 78 or the alternative adapter seal 79. The interspace 12 is formed between the chamber wall 41 and the vessel wall 9. The ceiling 11 sealingly connects the adapter 46 to the vessel wall 9 via the upper frame end 64, so that a sealed enclosure or containment vessel 8 is formed overall. In this case, the adapter can be connected to the lid 11 by means of adapter fastening means 49, for example screwed, and the ceiling 11 can in turn be connected to the upper frame end 64 by means of fastening means 69, so that a frictional connection is also formed from the adapter 46 via the ceiling 11 to the frame 60 and further into the container wall 9. In the example shown in FIG. 11, the vessel wall 9 is of double-walled construction and includes an inner wall 98, an outer panel 99, and the intermediate space 122 therebetween. In this embodiment, the outer panel 99 slightly overhangs the upper frame end 64 and fills a major portion of the area of the recess 63. A sealed feedthrough 26 is provided for the passage of, for example, electrical connections from or to the exterior, to the environment 30.

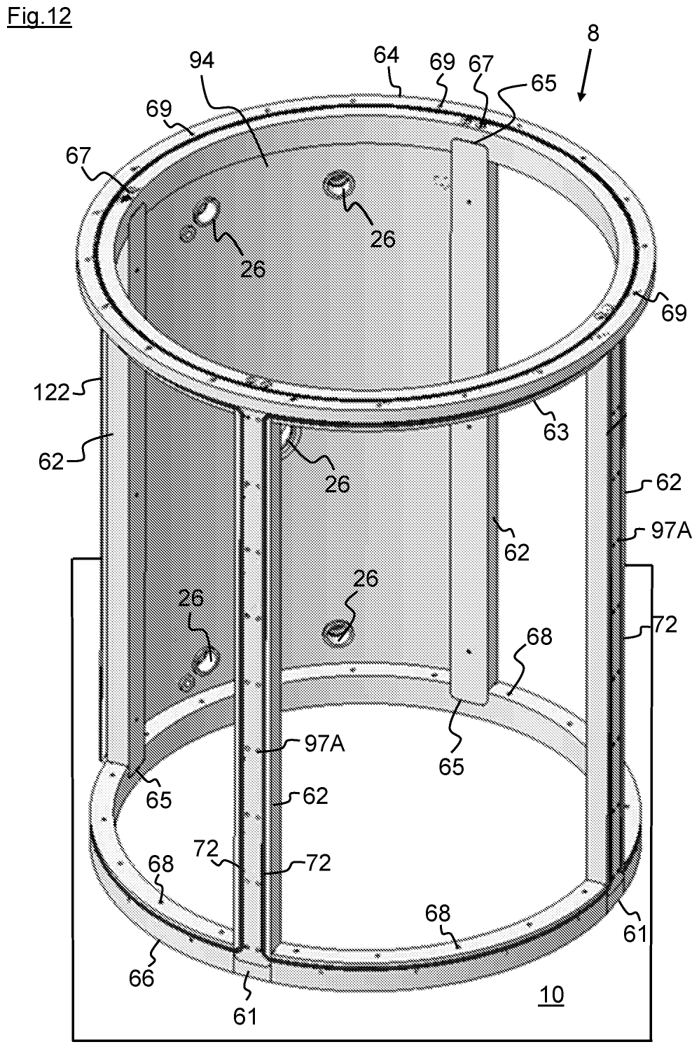

With FIG. 12, a partially assembled containment vessel 8 is shown, wherein a wall segment in the form of the connection segment 94 is already arranged on the frame 60 fixed to the floor 10. A plurality of sealed feedthroughs 26 provide a means for connecting electronics or the like located outside the containment vessel 8 to components located inside the containment vessel 8. If these component connections are combined such that a plurality of the or all of the provided connections are made through the connection segment 94, then the connection segment 94 may be arranged or configured to remain permanently or at least predominantly mounted. In contrast, other wall segments 91, 92, 93 may be configured to be quickly and easily removable so as to allow expeditious access to the process chamber 4. As usual and throughout the present description, the same reference signs represent the same elements, so that it would not be necessary to repeat the description of the plurality of elements already described below.

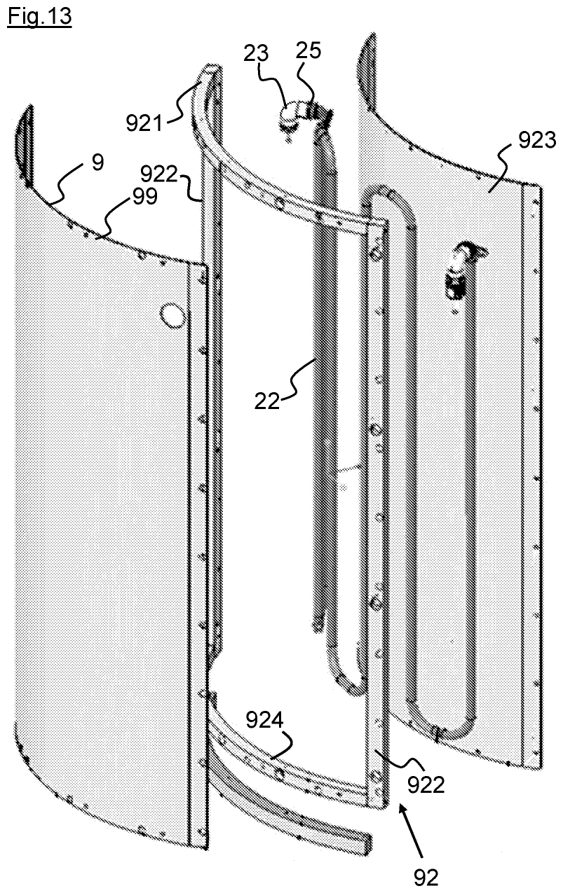

Referring to FIG. 13, a further embodiment of the cooling wall segment 92 with sandwich structure is further clarified. The coolant line 22 of the temperature control device 21 is arranged on the inner wall 98 and can be connected to the outside by means of connections 23. An interspace cover 921, 922 surrounds or delimits the segment 92 circumferentially, and an outer panel 99 can be screwed onto the interspace cover. With the outer panel 99, the coolant line 22 and the fastening element 97 are covered and thus protected from access on the one hand and from improper damage on the other hand. Thus, the outer panel 99 hides the technical installations from direct view and access and gives the apparatus 100 an attractive appearance. Furthermore, it can already be illustrated with FIG. 13 that the temperature control device 21 is also optimized to be able to remove the cooling wall element 92 as a whole quickly and easily, for example by providing connection pieces 23 at which the coolant line can be easily disconnected. For example, the connection pieces can be designed as quick connectors which have bayonet or screw locks and can be removed easily and quickly. Thus, the complete cooling wall element 92 can be easily separated from the coolant supply and thereby detached from the container assembly along with the cooling device (coolant line 22) as a whole. This further simplifies and expedites disassembly and/or opening of the containment vessel 8 in the event that maintenance intervention and/or replacement of the process chamber 4 is desired. Thus, although the double-walled structure of the wall segments 91, 92, 93, 94 is not absolutely necessary, and other arrangements of the coolant line 22 are also conceivable, the arrangement of the coolant line on the outside of the inner wall 923 has proved to be particularly advantageous, since the coolant line is thereby also arranged outside the interspace 12 to be sealed, and overall, in addition to the simpler dismantling and/or assembly of the containment 8 as a whole, also fewer lead-throughs through the vessel wall 9 to be sealed are required.

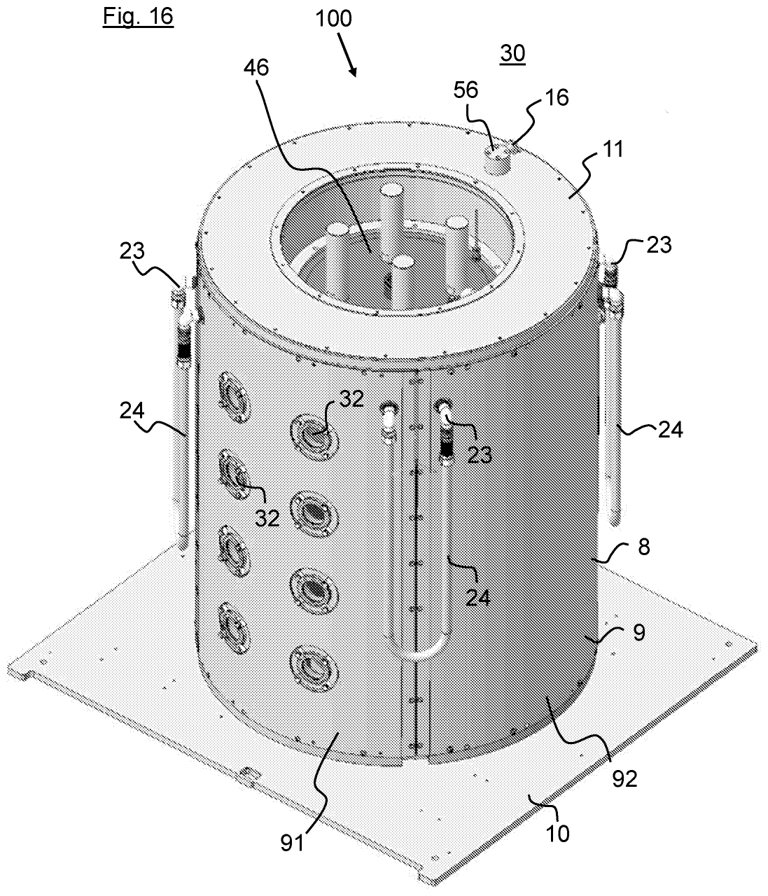

With reference to FIG. 15, a top view of the intermediate space 122 in the double wall of the cooling wall segment 92 of the vessel wall 9 is shown with temperature control device 21, the coolant line 22 being arranged in the intermediate space 122 in the vessel wall 9. In the case shown here, the vessel wall 9 comprises an inner wall 98, wall segments 92, 94 and the coolant line 22 of the temperature control device 21, which is arranged in an intermediate space 122. Wall segments 92, 94 are fastened to the segment 91 by fastening element 97. Further fastening means 96 (e.g., screw holes) are arranged at regular intervals on the wall segments 92, 94 so that the intermediate space 122 is enclosed thereby.

Finally, FIG. 16 shows an apparatus 100 mounted on the floor 10 with a multi-part container wall 9 comprising wall segments 91 and 92. The coolant lines 22 (cf., e.g., FIG. 15 or 13) run protected behind the outer panel 99 and are connected to each other in a communicating manner by means of compensating bends 24, so that a coolant-e.g., water-can flow through the temperature control device 21. In addition, the compensating bends 24 are quickly removable so that the coolant lines 22 and thus the wall segments 91, 92 as a whole are easily detachable from one another. The process chamber 4 (cf. e.g., FIG. 1 or 3) is surrounded on all sides by the safety atmosphere in the interspace 12—or, depending on the embodiment, in any case surrounded on all sides by the safety atmosphere above the floor 10. If the process chamber 4 bursts or otherwise fails and process gas escapes, the process gas mixes with the protective gas kept in the interspace 12 to form a harmless mixed gas.

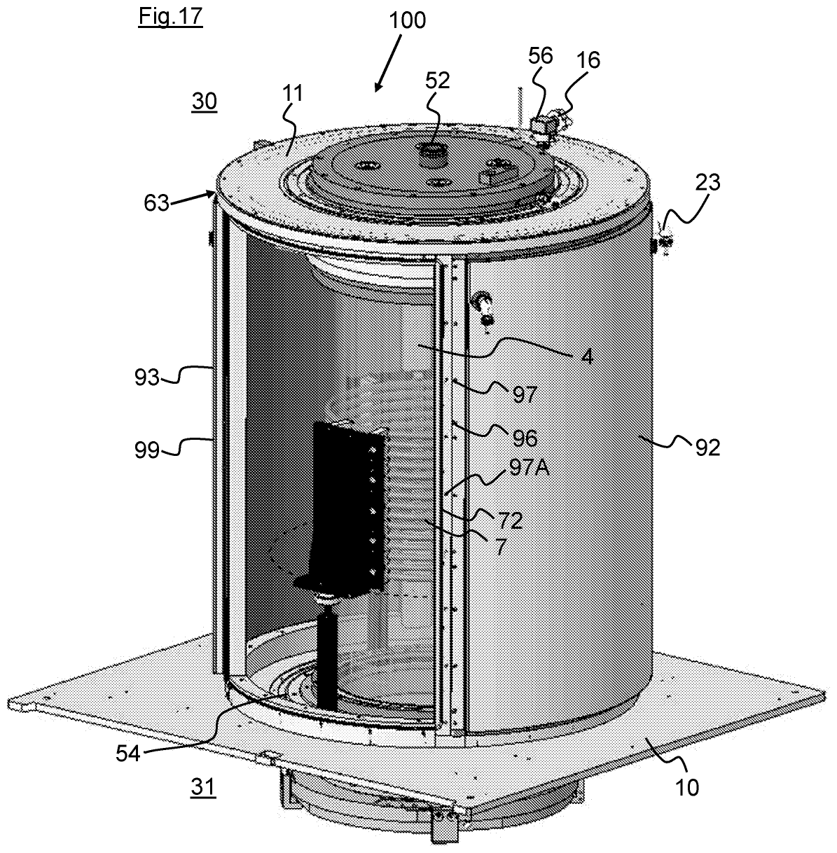

Referring to FIG. 17, a further embodiment of an apparatus 100 is shown, wherein the connection segment 94 is removed and a respective cooling wall element 92, 93 is mounted. In this embodiment, it is clear and/or different from the further embodiments that gas supply and discharge lines 51, 54 can be routed below the floor 10 so that they extend outside the environment 30 and are thus not in the area against which the containment 8 would have to protect. Thus, the subfloor 31 can be protected in other ways or it is not necessary at this place that protection would be provided by the containment atmosphere. Consequently, the process chamber 4 does not extend far enough into the subfloor 31, or into the subfloor 31 at all, so that no corresponding heating and/or any cracking of the chamber wall 41 at all is to be expected there, which would lead to a significant outflow of process gas into the subfloor 31, or which could lead to such a deflagration that a hazard would be expected in the surrounding environment 30. This also has the further advantage that fewer feedthroughs need to be routed through or into the interspace 12, thus further increasing the tightness of the containment vessel 8. A further advantage arises from the fact that the supply and discharge lines below the floor 10 do not interfere in the environment 30, but can rather be laid concealed.

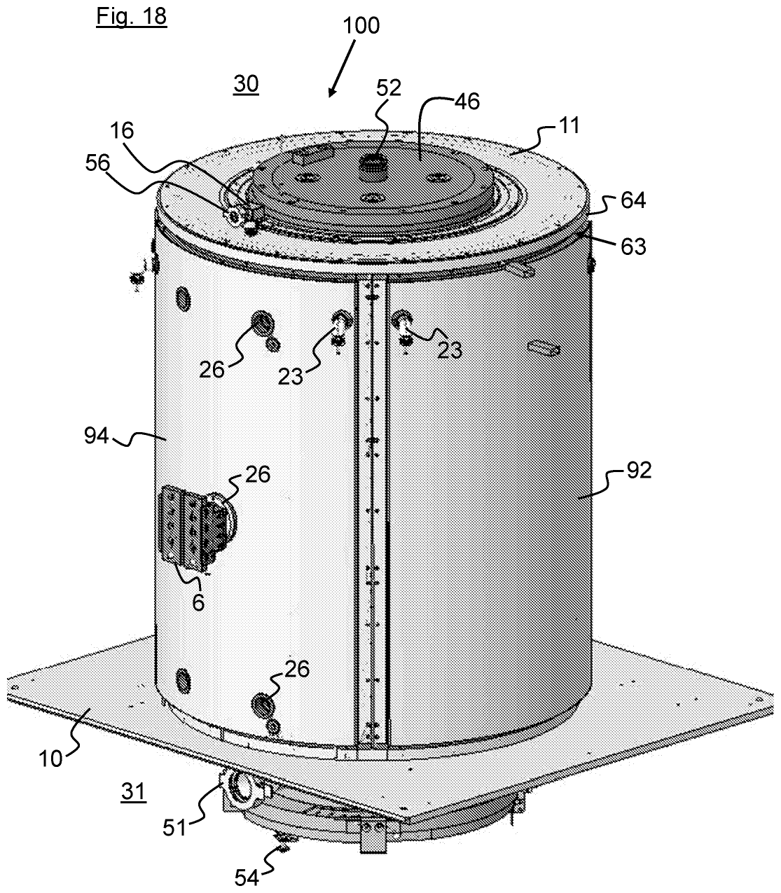

Finally, FIG. 18 shows another embodiment of a fully enclosed apparatus 100, in which a cooling wall segment 92 is inserted on the right-hand side and a connection segment 94 is inserted on the left-hand side. The heating electronics 6 are only schematically indicated and are arranged outside the containment vessel 8. The flange-like arrangement directly on the vessel wall 9 without hose-like intermediate connectors provides a further improved gas seal, so that this electronics flange is preferred for the heating device 6. Since this may mean a comparatively rigid arrangement of the connection segment 94, it may therefore be preferred to better remove the cooling wall element 92 for the purpose of replacing the process chamber 4 or generally for maintenance access and thus gain access to the process chamber and/or the induction heater, etc. Alternatively or cumulatively, of course, the ceiling 11 or adapter 46 may be removed and the process chamber taken out upwardly so that the hardware and electronics or gas connections, etc., located in the containment vessel 8 need not be removed or modified.

It has been shown that the modular concept of the further developments and present disclosure presented herein provides an enormous improvement and safety gain over earlier apparatus, while reducing manufacturing costs and simplifying the maintainability of the system components. Overall, the present description has a variety of aspects which, individually or together with others, may define significant aspects of the present disclosure.

It is apparent to those skilled in the art that the embodiments described above are to be understood as illustrative and that the invention is not limited to these, but can be varied in a variety of ways without departing from the scope of protection of the claims. Furthermore, it is apparent that the features, whether disclosed in the description, the claims, the figures or otherwise, also individually define components of the present disclosure, even if they are described together with other features. In all figures, the same reference signs represent the same objects, so that descriptions of objects which may be mentioned in only one or in any case not with respect to all figures can also be transferred to these figures and embodiments with respect to which the object is not explicitly described in the description.

1. PVT method for process-safe production of single crystals in an apparatus, wherein the apparatus comprises a process chamber for receiving a heatable growth cell and a heating device for heating the growth cell, wherein the growth cell is adapted to receive a source material and a seed, and wherein the process chamber is fillable with a process gas and the growth cell is heatable, wherein the apparatus comprises a segmented containment vessel enclosing the process chamber, and wherein the containment vessel has at least first and second segments, the segments as a whole enclosing the process chamber at least radially so that an interspace is provided between the segments of the containment vessel and the process chamber, the PVT method comprising the steps of
providing a protective atmosphere in the interspace and therefore flooding the interspace with the protective atmosphere,
providing the process gas in the process chamber,
heating the growth cell using the heating device so that the source material sublimates and resublimates at the seed.

2. The PVT method set forth in claim 1,
wherein the step providing the protective atmosphere in the interspace includes adjusting an overpressure with respect to an ambient pressure in an environment surrounding the apparatus of at least 1 mbar above ambient pressure, and/or
wherein the process gas comprises a reactive gas.

3. The PVT method set forth in claim 1,
wherein the heating of the growth cell is effected from radially all sides using the heating device annularly surrounding the process chamber, and/or
ensuring that provision of the protective atmosphere in the interspace is completed before the process gas is introduced into the process chamber and/or the growth cell is heated to operating temperature, and/or
wherein the flooding of the interspace with the protective atmosphere further comprises displacing air present in the interspace before the sublimation of the source material is initiated.

4. The PVT method set forth in claim 1, wherein the process gas comprises hydrogen, and/or the protective atmosphere comprises an inert gas, the inert gas.

5. The PVT method set forth in claim 1, wherein the containment vessel is constructed to allow gas losses to an environment surrounding the apparatus, and inert gas is supplied to compensate for gas losses.

6. The PVT method set forth in claim 1, wherein for flooding the containment vessel, a first inert gas heavier than air is admitted into its lower region, the air being displaced upwards, for which purpose a closable outlet at an upper end of the containment vessel remains open until the air has escaped.

7. The PVT method set forth in claim 4, wherein, after flooding the containment vessel once or several times with a first inert gas, the first inert gas is replaced by a second inert gas.

8. The PVT method set forth in claim 1, wherein the containment vessel comprises a gas sensor capable of detecting the process gas and/or a process gas supply to the process chamber is interrupted when the process gas is detected in the containment vessel.

9. An apparatus for process-safe production of single crystals, comprising
a process chamber for accommodating a highly heatable growth cell, and
a heating device for heating the growth cell,
wherein the process chamber has a process gas connection for filling the process chamber with a process gas which can be provided from a process gas source,
wherein the growth cell is adapted to receive a source material and a seed,
the apparatus further comprising a segmented vessel wall enclosing the process chamber at least radially on all sides, the vessel wall comprising a plurality of at least two wall segments.

10. The apparatus set forth in claim 9,
wherein the vessel wall comprises the wall segments include at least one of:
a lead-through or connection segment,
a testing or inspection segment,
a cooling segment,
a lid segment, or
a base segment.

11. The apparatus set forth in claim 9,
wherein the vessel wall is designed to also enclose the process chamber from above and/or below, such as to completely enclose it on all sides, and/or
wherein the vessel wall comprises a process chamber adapter for receiving process chambers of different sizes with the vessel wall.

12. The apparatus set forth in claim 9,
further comprising a support frame for supporting at least two of said wall segments on said support frame.

13. The apparatus set forth in claim 12,
wherein the support frame is of multi-part construction, and/or
wherein the support frame has a plurality of at least two frame elements which can be detachably fastened to one another, and/or
wherein the support frame comprises at least one of
a cover element,
a plurality of rod elements or
a base element.

14. The apparatus set forth in claim 13,
wherein has at least one longitudinal groove (81, 82, 83, 84, 85, 86, 86A) on an outer side for receiving a sealing element, and/or
wherein the support frame is configured to receive a segment seal, and/or to receive a lid seal, and/or to receive a bottom seal.

15. The apparatus set forth in claim 13,
wherein the cover element is formed in one piece, for a placement on the rod elements, and/or
wherein the cover element is connected to the base element via the rod elements, and/or
wherein the elements of the support frame are detachably connectable to one another, by bolting, to provide a stable construction and to be dismountable for purposes of maintenance or opening of the apparatus.

16. The apparatus set forth in claim 13,
wherein the base element is multi-part and has base attachment portions and intermediate portions and is adapted such that the rod elements can be placed between the base attachment portions and on the intermediate portions, or
wherein the base element is one-part and the rod elements can be inserted into recesses of the base element, and/or
wherein the cover element is made in one piece and the rod elements can be inserted into recesses in the cover element, and/or
wherein the cover element forms a laterally projecting collar so that the wall segments can be fitted below the cover element without the wall segments projecting laterally beyond the cover element.

17. The apparatus forth in claim 12,
wherein the support frame is formed as an electrical insulator, and/or
wherein the support frame is non-magnetic, and/or
wherein the support frame is formed of temperature resistant material, and/or
wherein the support frame comprises ceramic, plastic, or a composite material or a combination thereof.

18. The apparatus set forth in claim 12,
wherein the support frame forms a retaining structure for receiving the wall segments on the support frame, so that the support frame and wall segments together form the vessel wall of a containment vessel, for enclosing the process chamber.

19. The apparatus set forth in claim 18,
wherein an intermediate space is provided between the vessel wall of the containment vessel and the process chamber, which is arranged such that the intermediate space can be flooded with a protective atmosphere, and/or
wherein the containment vessel encloses the process chamber on all sides.

20. The apparatus set forth in claim 9,
wherein the heating device surrounds the process chamber, and/or
wherein the heating device is formed annularly around the process chamber.

21. The apparatus set forth in claim 9,
wherein the vessel wall is designed in a double-walled manner,
wherein a cooling device is arranged in an intermediate region of the vessel wall.

22. The apparatus set forth in claim 18,
wherein the containment vessel is constructed to allow gas leakage externally, and/or
wherein the containment vessel comprises a pressure sensor and the pressure sensor is signal-connected to a control device, and/or
wherein the control device is designed to set an overpressure relative to an environment surrounding the apparatus in the containment vessel based on pressure sensor signals.

23. The apparatus set forth in claim 18,
further comprising a protective gas port in a lower region of the containment vessel and a protective gas outlet in an upper region thereof.

24. A multi-part support frame for supporting at least two wall segments on the support frame, suitable for an apparatus as set forth in claim 9 for performing a PVT crystal growth process, the support frame comprising:
a top member,
a plurality of bar members, and
a bottom member, the support frame being formed as an electrical insulator and being non-magnetic, wherein the support frame forms a holding structure for receiving the wall segments on the support frame, such that the support frame and wall segments together form a vessel wall of a containment vessel ( for enclosing a process chamber for performing the PVT crystal growth process.
